(19) United States
(12) Patent Application Publication
(10) Pub. No.: US 2014/0150851 A1
(43) Pub. Date: Jun. 5, 2014

(54) PHOTOVOLTAIC MODULE

(71) Applicant: FUJI ELECTRIC CO., LTD., Kawasaki-shi, Kanagawa (JP)

(72) Inventors: Taketo Tsuji, Chiba-shi (JP); Takehito Wada, Funabashi-shi (JP)

(73) Assignee: FUJI ELECTRIC CO., LTD., Kawasaki-shi, Kanagawa (JP)

(21) Appl. No.: 13/697,250

(22) PCT Filed: Feb. 3, 2012
(86) PCT No.: PCT/JP2012/052470

§ 371 Date: Dec. 20, 2012

(30) Foreign Application Priority Data
Jul. 20, 2011 (JP) 2011-158569

(51) Int. Cl. H01L 27/142

(52) U.S. Cl. CPC H01L 27/1421
USPC 136/251

(57) ABSTRACT

A photovoltaic module has a photovoltaic cell assembly and a diode assembly. The photovoltaic cell assembly is formed by stacking a rear surface electrode layer, a photoelectric conversion layer, and a transparent electrode layer on one surface of a substrate, and an electrode layer formed on the other surface of the substrate. The diode assembly is formed by sequentially stacking a first electrode layer, a semiconductor layer, and a second electrode layer on one surface of a second substrate. The first electrode layer or the second electrode layer of the diode assembly is formed of a conductive oxide. The electrode layer formed on the other surface of the substrate of the photovoltaic cell assembly and the electrode layer of the diode assembly surface-contact and electrically connected with each other. The photovoltaic cell assembly and the diode assembly are sealed and integrated with each other by a sealing member.

### TECHNICAL FIELD

The present invention relates to a photovoltaic module with a bypass diode.

### BACKGROUND ART

A photovoltaic module is designed by electrically connecting a plurality of photovoltaic cells in series to obtain a predetermined output.

Incidentally, in a non-electricity generating state of a photovoltaic battery (when the sunlight irradiated to the photovoltaic battery is blocked), the resistance of photovoltaic cells increases, generating heat. This might cause thermal damage to the photovoltaic cells. In order to prevent such damage to the photovoltaic cells, the photovoltaic battery is provided with a bypass diode in which diodes are connected electrically in parallel to the photovoltaic cells and a current is bypassed from the diodes when a shadow or other problem occurs in part of the photovoltaic cells.

In a standard bypass diode, mold diodes are connected to the outside of photovoltaic cells. However, this type of bypass diode has poor attachment workability because each of the mold diodes needs to be disposed in each of the photovoltaic cells. Disposing the diodes outside the photovoltaic cells increases the area of a section not contributing to the generation of electricity, lowering the generation of electricity per area.

Patent Document 1 discloses a configuration in which a metallic electrode, an amorphous silicon layer, and a metal electrode are stacked sequentially in this order on a flexible thin film to configure a diode, and an exposed part of the metallic electrode of the diode is adhered to and disposed on a metallic electrode of a photovoltaic cell with an adhesive such as conductive paste.

Patent Document 1: Japanese Patent Application Publication No. S59-94881

The diode of Patent Document 1 is configured by holding the amorphous silicon layer between the pair of metallic electrodes. However, metals such as Al and Ag diffuse mutually with Si, and the amorphous silicon layer functioning as the diode is thin. Thus, forming the metal electrodes on the amorphous silicon layer causes metallic diffusion on the amorphous silicon layer, generating a leak path easily. Consequently, the amorphous silicon layer might lose the ability to function as the diode.

Moreover, in some cases heat is generated as currents are concentrated in a joint section between a diode and a photovoltaic cell. In such a case, a sealing member that covers the photovoltaic cell and the diode becomes soft or melts, which might cause poor appearance such as swelling and deformation in the sealing member.

### DISCLOSURE OF THE INVENTION

An object of the present invention is to provide a photovoltaic module having a bypass diode, which is unlikely to cause poor appearance such as swelling and deformation in a sealing member and has excellent electricity generation characteristics.

In order to achieve the object mentioned above, a photovoltaic module according to the present invention has:

a photovoltaic cell assembly in which a photovoltaic cell, which has a photoelectric converter configured by sequentially stacking a rear surface electrode layer, a photoelectric conversion layer, and a transparent electrode layer on one surface of a first substrate, and an electrode layer formed on the other surface of the first substrate, is divided into a plurality of photovoltaic unit cells on the first substrate and in which adjacent photovoltaic unit cells are electrically connected with each other in series; and

a diode assembly in which a diode, which has a diode part configured by sequentially stacking a first electrode layer, a semiconductor layer, and a second electrode layer on one surface of a second substrate, is divided into a plurality of diode unit cells that are arranged so as to correspond to an arrangement of the photovoltaic unit cells to which the diode is attached,

wherein the first electrode layer and/or the second electrode layer of the diode assembly is formed of a conductive oxide,

the electrode layer formed on the other surface of the first substrate of the photovoltaic cell assembly and the electrode layer of the diode assembly are in surface-contact and electrically connected with each other, and

the photovoltaic cell assembly and the diode assembly are sealed and integrated with each other by a sealing member.

In the photovoltaic module according to the present invention, it is preferred that the second substrate of the diode assembly be a flexible film substrate.

In the photovoltaic module according to the present invention, it is preferred that the semiconductor layer of the diode part be configured by PIN amorphous silicon or NIP amorphous silicon.

In the photovoltaic module according to the present invention, it is preferred that an area of the diode assembly attached to the photovoltaic cell assembly be equal to or less than an area of the photovoltaic cell assembly, and that the diode assembly be disposed so as not to project from an outer circumference of the photovoltaic cell assembly.

In the diode assembly of the photovoltaic module according to the present invention, it is preferred that the diode, which has the diode part configured by sequentially stacking the first electrode layer, the semiconductor layer, and the second electrode layer in this order on one surface of the second substrate, and a third electrode layer formed on the other surface of the second substrate, be divided into a plurality of diode unit cells on the second substrate, and that the third electrode layer be connected to the second electrode layer by a conductor that passes through a first through-hole penetrating through the second substrate, the first electrode layer, and the semiconductor layer and that is substantially insulated from the first electrode layer, and the third electrode layer be also connected to the first electrode layer of an adjacent diode unit cell by a conductor that passes through a second through-hole penetrating through the second substrate and that is substantially insulated from the second electrode layer.

In the photovoltaic cell assembly of the photovoltaic module according to the present invention, it is preferred that the photovoltaic cell, which has the first substrate, the photoelectric converter configured by sequentially stacking the rear surface electrode layer, the photoelectric conversion layer, and the transparent electrode layer in this order on one surface of the first substrate, and a back surface electrode layer formed on the other surface of the first substrate, be divided into a plurality of photovoltaic unit cells on the first substrate, and that the back surface electrode layer be connected to the transparent electrode layer by a conductor that passes through a first through-hole penetrating through the first substrate, the rear surface electrode layer, and the photoelectric conversion layer and that is substantially insulated from the rear surface electrode layer, and the back surface electrode layer be also electrically connected in series with the rear surface electrode layer of an adjacent photovoltaic unit cell by a conductor that passes through a second through-hole penetrating through the first substrate and that is substantially insulated from the transparent electrode layer.

In the photovoltaic module according to the present invention, because the first electrode layer and/or the second electrode layer of the diode assembly is formed of a conductive oxide, and the conductive oxide is unlikely to diffuse mutually with Si, generation of a leak path in the diode part can be lowered.

Moreover, the conductive oxide has a greater resistance than Al or Ag. The use of the conductive oxide as an electrode material of the diode concentrates currents into a contact section between the diode and each photovoltaic cell upon application of currents. In the present invention, however, the electrode layer formed on the other surface of the first substrate of the photovoltaic cell assembly and the electrode layer of the diode assembly are in surface-contact and electrically connected with each other, preventing local concentration of currents upon application thereof, as well as excessive temperature increase. Therefore, melting, swelling and the like of the sealing member can be prevented.

### BRIEF DESCRIPTION OF THE DRAWINGS

FIG. 1 is a schematic diagram of an embodiment of a photovoltaic module according to the present invention;

FIG. 2 is a bottom view of the photovoltaic module;

FIG. 3 is an exploded perspective view of a photovoltaic cell assembly and diode assembly of the photovoltaic module;

FIG. 4 is a plan view of a transparent electrode layer (second electrode layer) of the photovoltaic cell assembly (diode assembly) of the photovoltaic module;

FIG. 5 is a plan view of a back surface electrode layer (third electrode layer) of the photovoltaic cell assembly (diode assembly) of the photovoltaic module;

FIG. 6 is a diagram showing a joint state between the photovoltaic cell assembly and the diode assembly of the photovoltaic module; and

FIG. 7 is a diagram showing a joint state between the photovoltaic cell assembly and the diode assembly of the photovoltaic module.

### BEST MODE FOR CARRYING OUT THE INVENTION

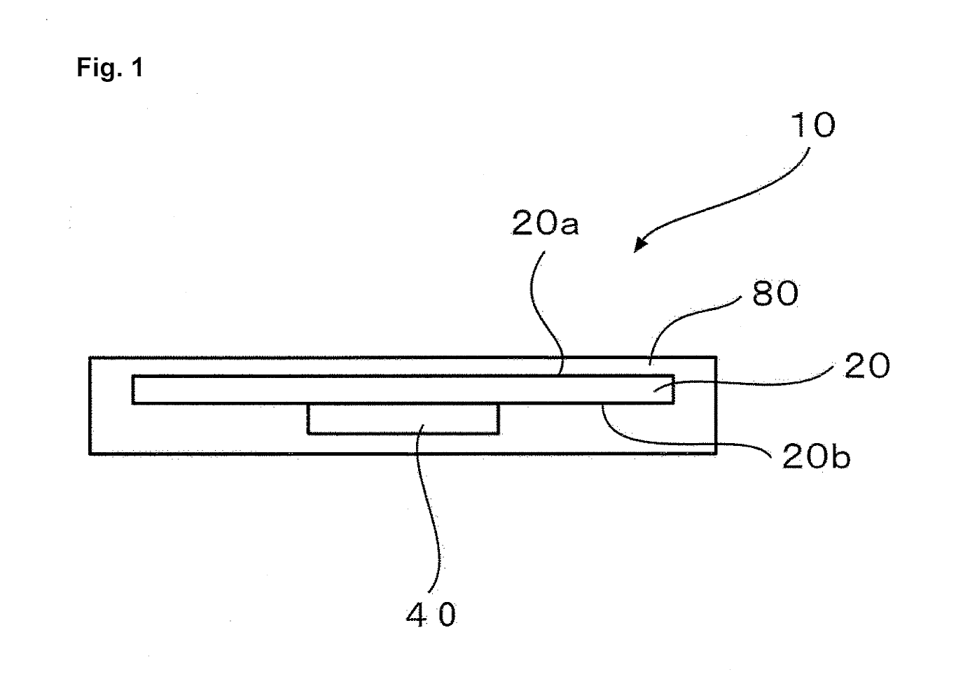

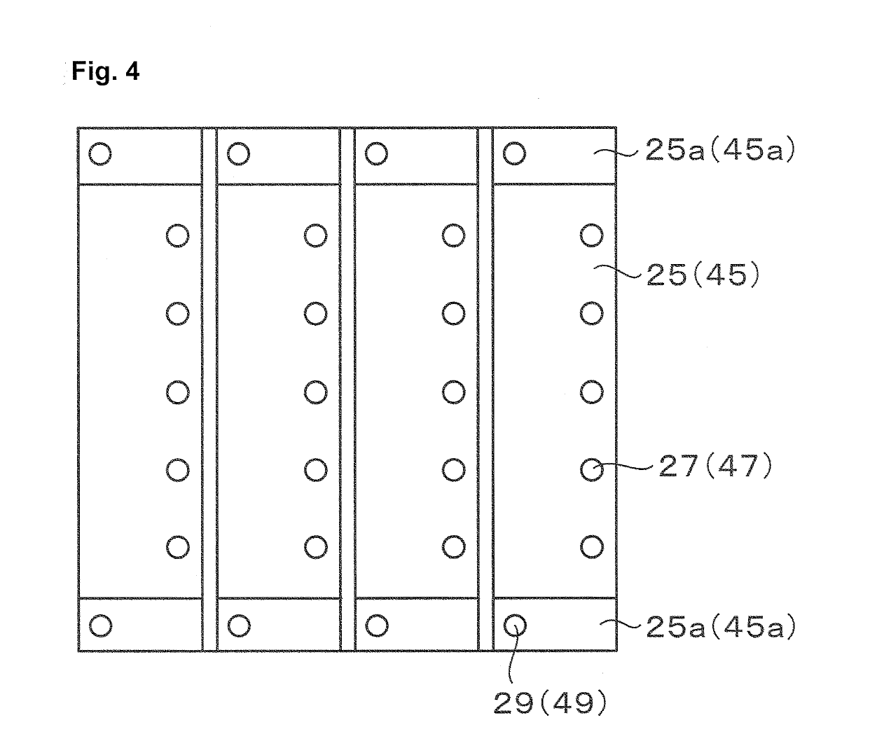

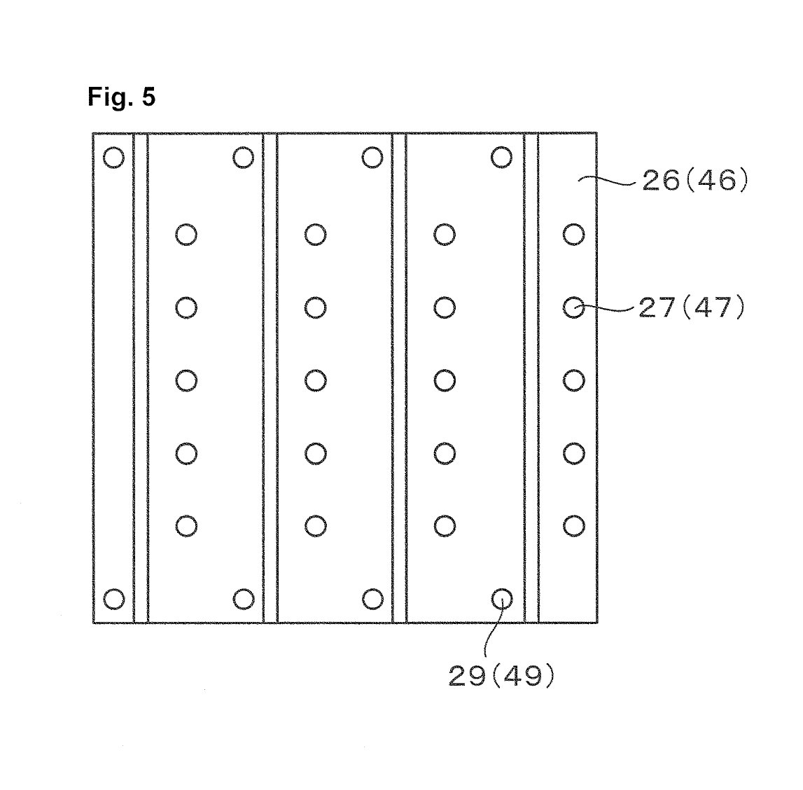

An embodiment of the photovoltaic module according to the present invention is described with reference to FIGS. 1 to 6.

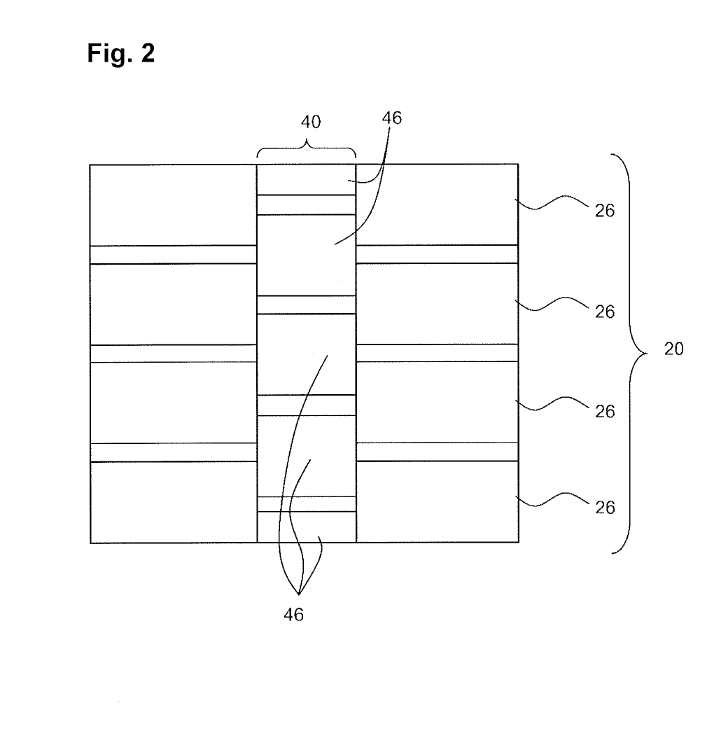

FIG. 1 is a schematic diagram showing a cross section of a photovoltaic module 10. FIG. 2 is a schematic diagram showing a bottom surface of the photovoltaic module 10. The photovoltaic module 10 is mainly configured by a photovoltaic cell assembly 20 and a diode assembly 40. The diode assembly 40 is configured such that an electrode layer of a non-light receiving surface 20b of the photovoltaic cell assembly 20 and an electrode layer of the diode assembly are pressure-bonded to each other, whereby these electrode surfaces surface-contact and are joined to each other. The diode assembly 40 and the photovoltaic cell assembly 20 are integrated and sealed by a sealing member 80. When viewing the bottom surface of the photovoltaic module 10, back surface electrode layers 26 (four, in FIG. 2) of photovoltaic unit cells constituting the photovoltaic cell assembly 20 are observed, and the diode assembly 40 having third electrode layers 46 (five, in FIG. 2) of diode unit cells is mounted thereon.

Although not particularly limited, it is preferred that the sealing member 80 has sealing resin and a surface protective material. A film with a certain degree of adhesiveness that is made of, for example, ethylene-vinyl acetate copolymer (EVA), epoxy resin, urethane resin, silicon resin, acrylic resin, polyisobutylene, or other resin material can be used as the sealing resin. A film made of a heat-resistant and weather-resistant material such as tetrafluoroethylene-ethylene copolymer, vinylidene fluoride resin, trifluoroethylene chloride resin, ETFE (ethylene tetrafluoroethylene), acrylic resin, trifluoroethylene chloride resin coat acrylic resin, polyester resin, or the like can be used as the surface protective material.

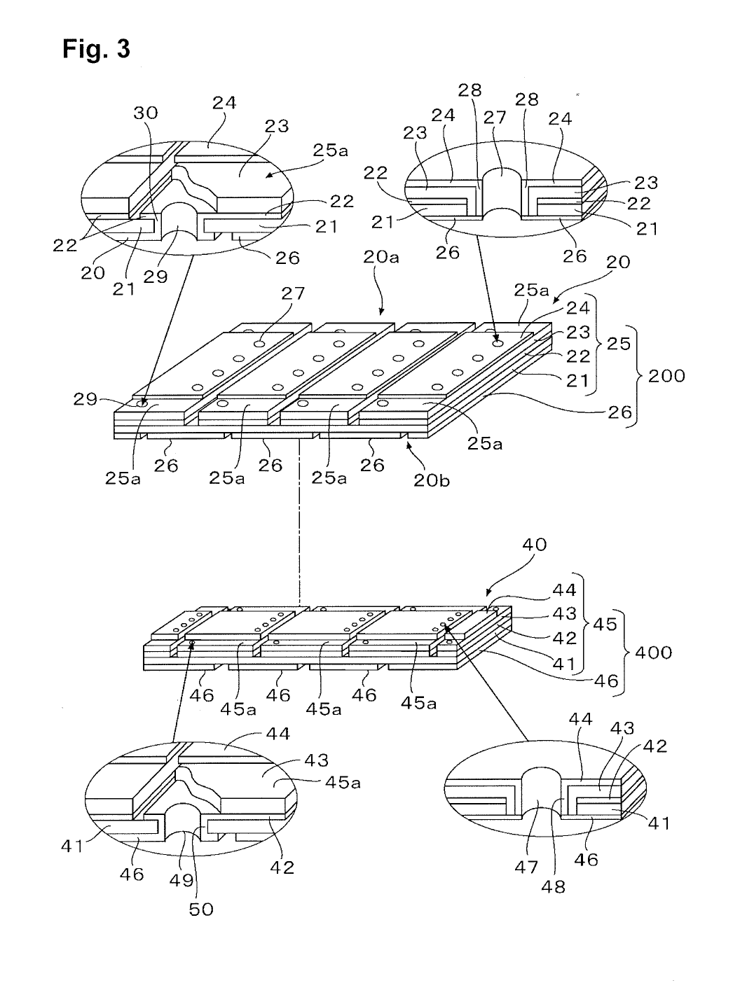

As shown in FIG. 3, in the photovoltaic cell assembly 20, a photovoltaic cell, which has a photoelectric converter 25 configured by sequentially stacking a rear surface electrode layer 22, a photoelectric conversion layer 23, and a transparent electrode layer 24 on a light-receiving surface 20a of a substrate 21 and the back surface electrode layer 26 formed on the non-light receiving surface 20b of the substrate 21, is divided into a plurality of photovoltaic unit cells 200, and adjacent photovoltaic unit cells 200 are connected electrically in series.

End parts of each photoelectric converter 25 are provided with connecting parts 25a, respectively, each of which is not provided with the transparent electrode layer 24 but has the rear surface electrode layer 22 and the photoelectric conversion layer 23 stacked sequentially on the substrate 21. The back surface electrode layers 26 are disposed at substantially the same intervals as the photoelectric converters of the photovoltaic unit cells 200, so as to be shifted toward the photoelectric converters on either one of the adjacent photovoltaic unit cells.

As shown in FIGS. 3 to 5, each of the photovoltaic unit cells 200 has a plurality of first through-holes 27 penetrating through the back surface electrode layer 26, the substrate 21, the rear surface electrode layer 22, the photoelectric conversion layer 23, and the transparent electrode layer 24, the first through-holes 27 being disposed at predetermined intervals. As shown in FIG. 3, the transparent electrode layer 24 and the back surface electrode layer 26 are electrically connected with each other by a conductor layer 28 through the first through-holes 27. The rear surface electrode layer 22 is covered with the photoelectric conversion layer 23 and therefore insulated from the transparent electrode layer 24, the conductor layer 28, and the back surface electrode layer 26.

Each of the connecting parts 25a has a second through-hole 29 penetrating through the back surface electrode layer 26, the substrate 21, the rear surface electrode layer 22, and the photoelectric conversion layer 23. The back surface electrode layer 26 and the rear surface electrode layer 22 are electrically connected with each other by a conductor layer 30 through the second through-holes 29.

A current is generated as a result of electricity generation in the photoelectric converter 25 and moves to the connecting parts 25a and then to the back surface electrode layer 26 of each photovoltaic unit cell 200 through the second through-holes 29. The current that moves to the back surface electrode layer 26 moves to the transparent electrode layer 24 of the adjacent photovoltaic unit cell 200 through the first through-holes 27. In this manner, the photovoltaic unit cells 200 of the photovoltaic cell assembly 20 are connected in series via the first through-holes 27 and the second through-holes 29. Such a structure is called SCAF (Series Connection through Apertures formed on Film), which can be produced by forming each electrode layer and the photoelectric conversion layer, patterning each of the layers, and performing a combination of these processes, by using, for example, the method disclosed in Japanese Patent Publication No. 3237621.

One example of producing the photovoltaic cell assembly 20 is now described. The rear surface electrode layer 22 is formed on the light-receiving surface of the substrate 21 in which each of the second through-holes 29 is opened. The back surface electrode layer 26 is formed on the non-light receiving layer. Consequently, the rear surface electrode layer 22 and the back surface electrode layer 26 are electrically connected with each other on inner walls of second through-holes 29. Next, the first through-holes 27 are opened so as to penetrate through the substrate 21, the rear surface electrode layer 22, and the back surface electrode layer 26. Subsequently, the photoelectric conversion layer 23 is formed on the entire surface of the light receiving surface of the substrate 21. Each end part is covered with a mask, and the transparent electrode layer 24 is formed thereon. Next, another back surface electrode layer is formed on the back surface electrode layer 26 of the substrate 21. In this manner, the transparent electrode layer 24 and the back surface electrode layer 26 are electrically connected with each other on inner walls of the first through-holes 27. Then, the photoelectric converter 25 and the back surface electrode layer 26 are segmented into predetermined shapes. As a result, the photovoltaic cell assembly with the abovementioned SCAF structure is produced.

A substrate with great heat resistance can preferably be used as the substrate 21. Examples of such a substrate include a glass substrate, a metallic substrate having a surface subjected to an insulation process, and a resin substrate. Above all, a flexible film substrate consisting of polyimide, polyethylene naphthalate, polyether sulfone, polyethylene terephthalate, aramid, or the like can preferably be used. A flexible photovoltaic cell assembly can be created using such a flexible film substrate. Although not particularly limited, it is preferred that the film thickness of the substrate 21 be approximately 15 to 200 μm, in view of flexibility, strength, and weight of the substrate 21.

Examples of the rear surface electrode layer 22 include, but not limited to, Ag, Ag alloy, Ni, Ni alloy, Al, and Al alloy.

Examples of materials for the photoelectric conversion layer 23 include, but not limited to, PIN or NIP amorphous silicon series and microcrystalline silicon thin films.

Examples of materials for the transparent electrode layer 24 include, but not limited to, ITO, SnO₂, and ZnO.

Examples of materials for the back surface electrode layer 26 include, but not limited to, Ag, Ag alloy, Ni, Ni alloy, Al, and Al alloy.

The diode assembly 40 is disposed on the non-light receiving surface 20b of the photovoltaic cell assembly 20. As shown in FIGS. 1 and 2, it is preferred that the area of the diode assembly 40 be equal to or less than that of the photovoltaic cell assembly 20 and that the diode assembly 40 be disposed so as not to project from an outer circumference of the photovoltaic cell assembly 20. Making the area of the diode assembly 40 greater than that of the photovoltaic cell assembly 20 or disposing the diode assembly 40 so as to project from the outer circumference of the photovoltaic cell assembly 20 increases the area of a section not contributing to the electricity generation of the photovoltaic module, resulting in lowering of the electricity generation efficiency per area in the photovoltaic module.

As shown in FIG. 3, the diode assembly 40 has a diode, which has a diode part 45 configured by sequentially stacking a first electrode layer 42, a semiconductor layer 43, and a second electrode layer 44 on one surface of a substrate 41. This diode is divided into a plurality of diode unit cells 400, which are arranged so as to correspond to the arrangement of the photovoltaic unit cells 200, to which the diode is attached.

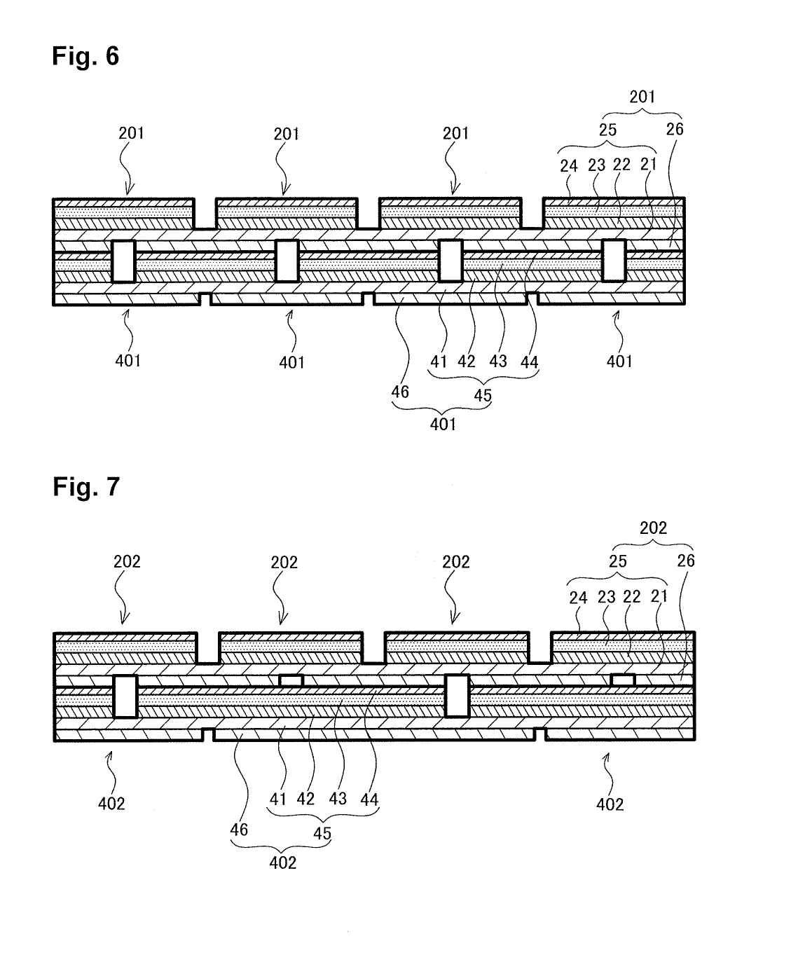

Here, “so as to correspond to the arrangement of the photovoltaic unit cells, to which the diode is attached” means that, when attaching diode unit cells 401 to photovoltaic unit cells 201 respectively (when attaching one diode unit cell to one photovoltaic unit cell) as shown in FIG. 6, the arrangement of the diode unit cells 401 and the arrangement of the photovoltaic unit cells 201 are in synchronization with each other. It also means that, when, as shown in FIG. 7, attaching one diode unit cell 402 to a plurality of (two, in FIG. 7) photovoltaic unit cells 202, the arrangement of the group of photovoltaic unit cells 202 to which the single diode unit cell 402 is attached is in synchronization with the arrangement of the diode unit cells 402.

In the case of FIG. 6, the width of each diode unit cell 401 is preferably smaller than that of each photovoltaic unit cell 201. The width of each diode unit cell 401 may be equal to that of each photovoltaic unit cell 201, but when the widths of the two photovoltaic unit cells are equal to each other, higher alignment accuracy is required, resulting in degradation of attachment workability. Therefore, each diode unit cell 401 and each photovoltaic unit cell 201 can be aligned easily by making the width of each diode unit cell 401 smaller than that of each photovoltaic unit cell 201.

In the case of FIG. 7, on the other hand, the width of each diode unit cell 402 is preferably smaller than that of the group of photovoltaic unit cells 202. Although the width of the diode unit cell 402 may be equal to that of the group of photovoltaic unit cells 202, the diode unit cell 402 and the group of photovoltaic unit cells 202 can be aligned easily by making the width of the diode unit cell 402 smaller than that of the group of photovoltaic unit cells 202.

Referring to FIG. 3 again, this diode assembly 40 has the same SCAF structure as the photovoltaic cell assembly 20 described above.

In other words, a diode, which has the diode part 45 configured by sequentially stacking the first electrode layer 42, the semiconductor layer 43, and the second electrode layer 44 in this order on one side of the substrate 41 and the third electrode layer 46 formed on the other side of the substrate 41, is divided into the plurality of diode unit cells 400.

End parts of each diode part 45 are provided with connecting parts 45a, respectively, each of which is not provided with the second electrode layer 44 but has the first electrode layer 42 and the semiconductor layer 43 stacked sequentially in this order. The third electrode layers 46 are disposed at substantially the same intervals as the diode parts of the diode unit cells 400, so as to be shifted toward the diode parts on either one of the adjacent diode unit cells.

As shown in FIGS. 3 to 5, each of the diode unit cells 400 has a plurality of first through-holes 47 penetrating through the third electrode layer 46, the substrate 41, the first electrode layer 42, the semiconductor layer 43, and the second electrode layer 44, the first through-holes 47 being disposed at predetermined intervals. The second electrode layer 44 and the third electrode layer 46 are electrically connected with each other by a conductor layer 48 through the first through-holes 47. The first electrode layer 42 is covered with the semiconductor layer 43 and therefore insulated from the second electrode layer 44, the conductor layer 48, and the third electrode layer 46.

Each of the connecting parts 45a has second through-holes 49 penetrating through the third electrode layer 46, the substrate 41, the first electrode layer 42, and the semiconductor layer 43. The third electrode layer 46 and the first electrode layer 42 are electrically connected with each other by a conductor layer 50 through second through-holes 49.

One example of producing the diode assembly 40 is now described. The first electrode layer 42 is formed on one side of the substrate 41 in which the second through-holes 49 are opened. The third electrode layer 46 is formed on the other side of the substrate 41. Consequently, the first electrode layer 42 and the third electrode layer 46 are electrically connected with each other on inner walls of the second through-holes 49. Next, the first through-holes 47 are opened so as to penetrate through the substrate 41, the first electrode layer 42, and the third electrode layer 46. Subsequently, the semiconductor layer 43 is formed on the entire surface of the first electrode layer 42 of the substrate 41. Each end part is covered with a mask, and the second electrode layer 44 is formed thereon. Next, another third electrode layer 46 is formed on the third electrode layer 46 of the substrate 41. In this manner, the second electrode layer 44 and the third electrode layer 46 are electrically connected with each other on inner walls of the first through-holes 47. Then, the diode part 45 and the third electrode layer 46 are segmented into predetermined shapes. As a result, the diode assembly with the abovementioned SCAF structure is produced.

The diode assembly 40 is joined to the non-light receiving surface 20b of the photovoltaic cell assembly 20. The diode unit cells 400 are electrically connected in parallel with the photovoltaic unit cells 200 in the opposite polarity direction. In this embodiment, the second electrode layer 44 of the diode assembly 40 and the back surface electrode layer 26 corresponding to the photovoltaic cell assembly contact with each other by being pressure-bonded to each other. As a result, the second electrode layer 44 and the back surface electrode layer 26 are joined to each other. Joining the electrode layer of the diode assembly 40 and the electrode layer of the photovoltaic cell assembly to each other by bringing them in to surface-contact with each other can prevent local concentration of currents upon application thereof, as well as excessive temperature increase. It should be noted that when bringing the second electrode layer 44 of the diode assembly 40 and the back surface electrode layer 26 corresponding to the photovoltaic cell assembly are pressure-bonded to each other and surface-contacted with each other, the second electrode layer 44 and the back surface electrode layer 26 may be temporarily joined to each other with adhesive tape, if needed. The tape may be stripped off after the second electrode layer 44 and the back surface electrode layer 26 are pressure-bonded to each other or may be sealed with the sealing member along with the photovoltaic cell assembly.

A substrate with great heat resistance can preferably be used as the substrate 41. Examples of such a substrate include a glass substrate, a metallic substrate having a surface subjected to an insulation process, and a resin substrate. It is preferred that the same material as that of the substrate 21 of the photovoltaic cell assembly 20 be selected. Above all, a flexible film substrate consisting of polyimide, polyethylene naphthalate, polyether sulfone, polyethylene terephthalate, aramid, or the like can preferably be used. The flexibility of the flexible diode assembly can be improved by such a flexible film substrate, without deteriorating the flexibility of the photovoltaic cell assembly. Furthermore, with the same material as that of the substrate 21 of the photovoltaic cell assembly 20, the thermal expansion coefficient of the photovoltaic cell assembly 20 can be made substantially equal to that of the bypass diode assembly 40, preventing stripping and deformation of the interface therebetween.

Although not particularly limited, it is preferred that the film thickness of the substrate 41 be approximately 15 to 200 μm, in view of flexibility, strength, and weight of the substrate 41.

Examples of materials for the first electrode layer 42, the second electrode layer 44, and the third electrode layer 46 include, but not limited to, conductive oxides such as ITO, SnO₂, and ZnO, and metals such as Ag, Ag alloy, Ni, Ni alloy, Al, and Al alloy. Above all, in the present invention, the first electrode layer 42 and/or the second electrode layer 44 is formed of the conductive oxide. Because the conductive oxide is unlikely to diffuse mutually with Si, generation of a leak path in the diode part 45 can be lowered, by forming the first electrode layer 42 and/or the second electrode layer 44 by using the conductive oxide.

Examples of materials for the semiconductor layer 43 include, but not limited to, PIN amorphous silicon, NIP amorphous silicon, and microcrystalline silicon thin films. Preferably, PIN amorphous silicon or NIP amorphous silicon is used due to its low on-voltage and excellent rectification property.

Because the diode unit cells 400 are electrically connected in parallel with the photovoltaic unit cells 200 in the opposite polarity direction, no current flows through the diode unit cells 400, while the photovoltaic unit cells 200 attached with the diode unit cells 400 generate electricity.

However, when, for example, some of the photovoltaic unit cells 200 fall under the shadow and stop generating electricity, electrons move from the back surface electrode layer 26 of one of adjacent photovoltaic unit cells 200 to the third electrode layer 46 of the corresponding diode unit cell 400. The current that moves to the third electrode layer 46 of the corresponding diode unit cell 400 moves to the first electrode layer 42 via the second through-holes 49. The current that moves to the first electrode layer 42 moves to the second electrode layer 44 via the semiconductor layer 43 and moves to the first through-holes 47. The current then moves to the third electrode layer 46 of the adjacent diode unit cell 400 via the first through-holes 47 and then to the back surface electrode layer 26 of the other photovoltaic unit cell 200 on the other side.

Thus, even when part of the photovoltaic module falls under the shadow and the sunlight emitted to some of the photovoltaic unit cells 200 is blocked, the current bypasses the photovoltaic unit cells 200 not generating electricity and then flows to the next photovoltaic unit cell 200. As a result, stable photovoltaic characteristics can be obtained.

The photovoltaic module of the present invention has the diode assembly 40 disposed on the non-light receiving surface of the photovoltaic cell assembly 20. Therefore, even when some of the photovoltaic unit cells 200 are kept away from the sunlight, stable photovoltaic characteristics can be obtained without degrading the electricity generation performance of the photovoltaic unit cells 200. Furthermore, when a film-like diode assembly configured by using a flexible film substrate as the substrate 41 is used as the diode assembly 40, the thickness and weight of the entire photovoltaic module do not increase much, due to the thin film structure and flexibility of the diode assembly 40. In addition, even when the photovoltaic cell assembly 20 is flexible, its flexibility is not deteriorated.

In this diode assembly 40, the diode part 45 is formed on the substrate such that the arrangement of the diode unit cells 400 corresponds to the arrangement of the photovoltaic unit cells 200 to which the diode unit cells 400 are attached. Therefore, the diode unit cells 400 and the photovoltaic unit cells 200 to which the diode unit cells 400 should be attached can be aligned easily, and the diode unit cells 400 can be attached to the photovoltaic unit cells 200 reliably with excellent workability.

The second electrode layer 44 of the diode assembly 40 and the back surface electrode layer 26 corresponding to the photovoltaic cell assembly are surface-contacted and electrically connected with each other, preventing local concentration of currents upon application thereof, as well as excessive temperature increase. Therefore, melting, swelling and the like of the sealing member can be prevented.

In this embodiment, although both the photovoltaic cell assembly 20 and the diode assembly 40 have the SCAF structure, either one of them may have the SCAF structure or both of them may have a structure other than the SCAF structure. When both the photovoltaic cell assembly 20 and the diode assembly 40 have the same structure such as the SCAF structure, the photovoltaic cell assembly 20 and the diode assembly 40 can be produced through the same production steps, enabling effective use of the manufacturing device.

Examples of the photovoltaic cell assembly having a structure other than the SCAF structure include a structure in which a plurality of photovoltaic unit cells are formed on a light-receiving surface of a substrate and wire-connected in series with each other, a structure in which a photoelectric conversion layer, transparent electrode layer and the like are formed on a conductive substrate and in which a plurality of collecting electrodes are provided at predetermined intervals on apart of the transparent electrode layer, and a structure in which a substrate itself constitutes a photoelectric conversion layer and an electrode layer is formed on the other side of a light-receiving surface. Moreover, examples of the diode assembly having a structure other than the SCAF structure include a structure in which a plurality of diode unit cells are formed on one surface of a substrate and wire-connected in series with each other.

In this embodiment, the photoelectric converter 25 has a substrate structure having the rear surface electrode layer, the photoelectric conversion layer, and the transparent electrode layer stacked sequentially in this order on a substrate. However, the photoelectric converter 25 may have a super straight structure having the transparent electrode, the photoelectric conversion layer, and the electrode layer stacked sequentially on a transparent substrate. Note that in the photovoltaic cell of the super straight structure, the transparent substrate side is the light-receiving surface and the electrode layer side is the non-light receiving surface, wherein the electrode layer side has the bypass diode assembly 40 disposed thereon.

Furthermore, in this embodiment, the back surface electrode layer 26 of each photovoltaic unit cell 200 and the second electrode layer 44 of each diode unit cell 400 are surface-contacted and joined with each other; however, the back surface electrode layer 26 of each photovoltaic unit cell 200 and the third electrode layer 46 of each diode unit cell 400 may be surface-contacted and joined with each other. Nonetheless, the diode unit cells 400 need to be connected in parallel with the photovoltaic unit cells 200 in the opposite polarity direction.

### EXPLANATION OF REFERENCE NUMERALS

10: Photovoltaic module

20: Photovoltaic cell assembly

21: Substrate

22: Rear surface electrode layer

23: Photoelectric conversion layer

24: Transparent electrode layer

25: Photoelectric converter

25a: Connecting part

26: Back surface electrode layer

27: First through-hole

28: Conductor layer

29: Second through-hole

30: Conductor layer

40: Diode assembly

41: Substrate

42: First electrode layer

43: Semiconductor layer

44: Second electrode layer

45: Diode part

45a: Connecting part

46: Third electrode layer

47: First through-hole

48: Conductor layer

49: Second through-hole

50: Conductor layer

80: Sealing member

200, 201, 202: Photovoltaic unit cell

400, 401, 402: Diode unit cell

1. A photovoltaic module, comprising:
a photovoltaic cell assembly in which a photovoltaic cell, which has a photoelectric converter configured by sequentially stacking a rear surface electrode layer, a photoelectric conversion layer, and a transparent electrode layer on one surface of a first substrate, and an electrode layer formed on the other surface of the first substrate, is divided into a plurality of photovoltaic unit cells on the first substrate and in which the adjacent photovoltaic unit cells are electrically connected with each other in series; and
a diode assembly in which a diode, which has a diode part configured by sequentially stacking a first electrode layer, a semiconductor layer, and a second electrode layer on one surface of a second substrate, is divided into a plurality of diode unit cells that are arranged to correspond to an arrangement of the photovoltaic unit cells to attach each diode,
wherein the first electrode layer and/or the second electrode layer of the diode assembly is formed of a conductive oxide,
the electrode layer formed on the other surface of the first substrate of the photovoltaic cell assembly and the electrode layer of the diode assembly surface-contact and electrically connected with each other, and
the photovoltaic cell assembly and the diode assembly are sealed and integrated with each other by a sealing member.

2. A photovoltaic module according to claim 1, wherein the second substrate of the diode assembly is a flexible film substrate.

3. A photovoltaic module according to claim 1, wherein the semiconductor layer of the diode part is configured by PIN amorphous silicon or NIP amorphous silicon.

4. A photovoltaic module according to claim 1, wherein an area of the diode assembly attached to the photovoltaic cell assembly is equal to or less than an area of the photovoltaic cell assembly, and
the diode assembly is disposed so as not to project from an outer circumference of the photovoltaic cell assembly.

5. A photovoltaic module according to claim 1, wherein in the diode assembly, the diode, which has the diode part configured by sequentially stacking the first electrode layer, the semiconductor layer, and the second electrode layer on one surface of the second substrate, and a third electrode layer formed on the other surface of the second substrate, is divided into a plurality of diode unit cells on the second substrate,
the third electrode layer is connected to the second electrode layer by a conductor substantially insulated from the first electrode layer and passes through a first through-hole penetrating through the second substrate, the first electrode layer, and the semiconductor layer, and
the third electrode layer is connected to the first electrode layer of the adjacent diode unit cell by a conductor substantially insulated from the second electrode layer and passes through a second through-hole penetrating through the second substrate.

6. A photovoltaic module according to claim 1, wherein in the photovoltaic cell assembly, the photovoltaic cell, which has the photoelectric converter configured by sequentially stacking the rear surface electrode layer, the photoelectric conversion layer, and the transparent electrode layer on one surface of the first substrate, and a back surface electrode layer formed on the other surface of the first substrate, is divided into a plurality of photovoltaic unit cells on the first substrate,
the back surface electrode layer is connected to the transparent electrode layer by a conductor substantially insulated from the rear surface electrode layer and passes through a first through-hole penetrating through the first substrate, the rear surface electrode layer, and the photoelectric conversion layer, and
the back surface electrode layer is electrically connected in series with the rear surface electrode layer of the adjacent photovoltaic unit cell by a conductor substantially insulated from the transparent electrode layer and passes through a second through-hole penetrating through the first substrate.

7. A photovoltaic module according to claim 5, wherein, in the photovoltaic cell assembly, the photovoltaic cell, which has the photoelectric converter configured by sequentially stacking the rear surface electrode layer, the photoelectric conversion layer, and the transparent electrode layer on one surface of the first substrate, and a back surface electrode layer formed on the other surface of the first substrate, is divided into a plurality of photovoltaic unit cells on the first substrate,
the back surface electrode layer is connected to the transparent electrode layer by a conductor substantially insulated from the rear surface electrode layer and passes through a first through-hole penetrating through the first substrate, the rear surface electrode layer, and the photoelectric conversion layer, and
the back surface electrode layer is electrically connected in series with the rear surface electrode layer of the adjacent photovoltaic unit cell by a conductor substantially insulated from the transparent electrode layer and passes through a second through-hole penetrating through the first substrate.
